(19) United States
(12) Patent Application Publication
(10) Pub. No.: US 2023/0341471 A1
(43) Pub. Date: Oct. 26, 2023

(54) BATTERY PERFORMANCE TRACKING ACROSS BATTERY CELLS

(71) Applicant: REON Technology, Inc., Chelmford, MA (US)

(72) Inventors: Xuanhang Zhang, Austin, TX (US); Tiegeng Ren, Westford, MA (US)

(73) Assignee: REON Technology, Inc., Chelmsford, MA (US)

(21) Appl. No.: 18/137,471

(22) Filed: Apr. 21, 2023

Related U.S. Application Data
(60) Provisional application No. 63/334,160, filed on Apr. 24, 2022.
(60) Provisional application No. 63/333,708, filed on Apr. 22, 2022.

(51) Int. Cl. G01R 31/396; H01M 10/48; G01R 31/392; G01R 31/36

(52) U.S. Cl. CPC G01R 31/396; H01M 10/482; G01R 31/392; G01R 31/3648

(57) ABSTRACT

Techniques for battery assessment based on battery performance tracking across battery cells are disclosed. A battery system comprising a plurality of battery cells is accessed. The plurality of battery cells comprises a plurality of battery columns made up of battery cells arranged in series. The plurality of battery columns is connected in parallel. Information is obtained on a battery cell within the plurality of battery cells. The information on the battery cell is tracked by a column controller for a battery column from the plurality of battery columns. The battery cell resides within the battery column. The information on the battery cell is stored for future reference. The stored information on the battery cell is analyzed. A capability metric for the battery cell is predicted based on the analyzing of the information on the battery cell. The battery cell information is obtained using near field communication.

### RELATED APPLICATIONS

This application claims the benefit of U.S. provisional patent applications “Battery System Management Using Cell State” Ser. No. 63/333,708, filed Apr. 22, 2022 and “Battery Performance Tracking Across Battery Cells” Ser. No. 63/334,160, filed Apr. 24, 2022.

Each of the foregoing applications is hereby incorporated by reference in its entirety.

### FIELD OF ART

This application relates generally to battery assessment and more particularly to battery performance tracking across battery cells.

### BACKGROUND

As electronic devices have continued to evolve and proliferate, batteries have taken on a new significance. Today, one would hardly purchase a device such as a phone, tablet, laptop, and so on without reviewing the battery specifications. In a world full of portable devices, consumers view battery life to be just as important as traditional performance metrics such as speed, throughput, memory capacity, and so on. While the design and use of portable devices has expanded, battery technology has not generally kept the same pace of improvement. Thus, the increased focus on battery life has influenced the design and marketing of components. For example, microprocessors are no longer designed exclusively for performance. Instead, performance-per-watt has risen in popularity and may be a more sustainable predictor of future compute performance than Moore's law. Better performance-per-watt metrics allow for longer battery life without requiring major improvements to battery technology. Today, most electronic devices are powered by lithium-ion batteries, which offer a variety of voltage, energy density, and safety profiles depending on internal chemistry. These batteries can be configured for a wide range of uses including watches and cell phones, solar power plants, and more. Yet, even better technology is in development. These new concepts hold the promise of improved voltage, power density, and temperature characteristics which will lead to both faster recharging and longer power delivery. A list of new technologies includes aluminum-ion, carbon nanotube, solid state lithium-ion, and lithium sulfur batteries. Regardless of which specific technologies are utilized, consumers will demand new and improved devices that leverage power improvements.

Consumers demand portability, and just about every device, whether cell phone, laptop, tablet, watch, and so on, requires a battery. The expansive and creative use of batteries throughout the consumer device market has enabled advancements in remote computing. It has also created entirely new markets and new categories of products. For example, consumer behavior regarding laptop purchases is not only influenced by performance metrics, but also by other factors such as battery life and even compatibility of charging cables. Laptops can be purchased from the manufacturer with different sized batteries, offering a tradeoff between battery life and weight. In some cases, multiple batteries can be purchased to enable longer runtimes. Third party vendors can offer additional cables and compatible chargers to maintain battery life in more than one location, ensuring maximum portability. The ubiquitous use of other devices such as cell phones and tablets have driven similar purchase options from third party vendors. For example, new technologies such as wireless charging now appear in bedrooms as well as in new cars. Many cell phone users purchase multiple charging cables with a plurality of form factors including USB micro, USB-A, USB-C, as well as other proprietary connectors. Powerful wall charging bricks, which convert AC electricity to DC for device charging, are now pervasive, some providing the convenience of charging multiple devices at once. Clearly, the widespread adoption of portable devices has spawned multiple markets to maintain battery power and has kept consumers on the go with their devices. As new devices are developed, along with new batteries, to power them, additional third-party markets will continue to emerge.

### SUMMARY

Rechargeable batteries are used for a multitude of applications. The battery applications range from renewable energy storage, to transportation, to powering personal electronic devices. Such batteries are also used to provide power to power grids, vehicles, and electronic devices. The batteries are then recharged so that the batteries again can power the equipment and devices in which the batteries are installed. Depending on the particular chemical composition of the rechargeable batteries, the batteries have different, finite charge-discharge cycle lifespans. In order to maintain equipment at manufacturer specifications, the rechargeable batteries require replacement from time to time. The replacement is required once the charge-discharge cycle limit has been reached, or sooner if one or more of the batteries encounter a problem. The in-service rechargeable batteries are removed, and other rechargeable batteries are installed in their places. The rechargeable batteries that are removed from service can be problematic. Batteries can leak their chemicals, become unstable, or even catch fire and explode. Recycling of rechargeable batteries is encouraged, but recycling the chemicals and materials used to construct the batteries can be costly and complicated.

Many of the batteries that are removed from service are still usable in various power storage applications. While the batteries may no longer have the storage capacity as when they were new, they can still be used to store some electrical energy. The rechargeable batteries can be scanned to obtain information, such as performance information, about the batteries. The performance information can be collected while the batteries are in use and can include data associated with temperature, current, voltage, impedance, and so on. In addition, the battery information can be tracked and analyzed. The tracking and analyzing of the batteries can be used to determine usability and capacity of the batteries. In order to use the batteries for new power applications, the batteries can be broken down into their component cells. Switches and scanners or sensors can be added to the cells to select or deselect the cells, to monitor cell “health”, and so on. The cells can be assembled into battery units or columns, and the battery columns can be coupled into battery systems. The battery cells can be selected when in use by the battery system or for recharging, and deselected when the cell is unneeded in a particular battery system or when the cell is inadequate to the task. Frequent monitoring of the cells can detect problems with one or more cells such as overheating, a short circuit, etc. Thus, problematic cells can be quickly removed from service and safely discharged, thereby reducing or eliminating the risk of fire or explosion.

A processor-implemented method for battery assessment is disclosed comprising: accessing a battery system comprising a plurality of battery cells, wherein the plurality of battery cells comprises a plurality of battery columns made up of battery cells arranged in series, wherein the plurality of battery columns is connected in parallel; obtaining information on a battery cell within the plurality of battery cells; tracking the information on the battery cell by a column controller for a battery column from the plurality of battery columns, wherein the battery cell resides within the battery column; storing the information on the battery cell for future reference; analyzing the information on the battery cell that was stored; and predicting a capability metric for the battery cell based on the analyzing of the information on the battery cell. In embodiments, the battery cell information is obtained using near field communication (NFC). In embodiments, the information on the battery cell includes a number of charge cycles and a number of discharge cycles. In embodiments, the information on the battery cell includes a source of energy that was used to charge the battery cell. In embodiments, the source of energy includes a renewable energy source. And in embodiments, a quantification number is calculated for an amount of carbon saved based on the renewable energy source.

Various features, aspects, and advantages of various embodiments will become more apparent from the following further description.

### BRIEF DESCRIPTION OF THE DRAWINGS

The following detailed description of certain embodiments may be understood by reference to the following figures wherein:

FIG. 1A is a flow diagram for battery performance tracking across battery cells.

FIG. 1B is a block diagram showing NFC protocol usage.

FIG. 2A illustrates columns of battery cells and switches in a battery system.

FIG. 2B is a flow diagram for battery system control.

FIG. 3 is a system block diagram for battery system management.

FIG. 4A illustrates example battery units.

FIG. 4B illustrates multiple battery unit configurations.

FIG. 5 is a system schematic diagram for battery management.

FIG. 6 illustrates a battery system index gauge.

FIG. 7 shows a block diagram for a blockchain with battery information metadata.

FIG. 8 is a system diagram for battery performance tracking across battery cells.

### DETAILED DESCRIPTION

Techniques for battery assessment based on battery performance tracking across battery cells are disclosed. Batteries of all kinds, whether single-use or rechargeable, are installed in a dizzying array of modern products. From personal care items, to quartz, digital and smart timepieces, to handheld and portable electronic devices, and to vehicles, batteries are used to power and enable convenient and often portable use of these and many other devices. As the use of electronic devices and vehicles has become significantly more prevalent, and the limitations of conventional and existing battery technologies have proven too limiting for practical use, researchers have sought advanced battery chemistries and configurations. The advanced batteries have shown great promise by reducing weight and volume, increasing energy densities, reducing energy leakage, and so on. These advanced batteries are finding increasing use in applications such as renewable energy storage, transportation, and personal electronic devices. The batteries are used to provide power to power grids when renewable sources are offline, to terrestrial vehicles and now to experimental aerial ones, and in about every electronic gadget imaginable. However, rechargeable batteries age over time, primarily due to charge/discharge cycling. In order to maintain operation of electrical equipment, electric vehicles, and electronic devices at manufacturer specifications, the rechargeable batteries require replacement from time to time. The replacement is indicated once the charge-discharge cycle limit has been reached, or at any time if one or more of the batteries encounter a problem. The in-service rechargeable batteries are removed and replaced with other rechargeable batteries. Rechargeable batteries that are removed from service have typically been sent for recycling. The batteries that were removed may no longer operate at their original storage and discharge levels, but they can still store and provide electrical energy storage and distribution for other applications.

The rechargeable batteries that are removed from service can be provided a “second life”. The rechargeable batteries can be scanned to collect battery cell information about the batteries. The battery cell information can be collected while the batteries are in use and can include data associated with charge/discharge cycle count, temperature, current, voltage, internal impedance, leakage, and so on. The batteries can be further analyzed to determine usability and capacity of the batteries. In order to use the batteries for new power applications, the batteries can be broken down into their component cells. Switches and scanners or sensors can be added to the cells to select or deselect the cells, to monitor cell “health”, and so on. The cells can be assembled into battery units or columns, and the battery columns can be coupled into battery systems. The battery cells can be selected when in use by the battery system or for recharging and deselected when the cell is unneeded in a particular battery system or when the cell is inadequate to the task. Frequent monitoring of the cells can detect problems with one or more cells, such as overheating, low impedance, etc. Thus, problematic or failed cells can be quickly removed from service and safely discharged, thereby reducing or eliminating the risk of fire or explosion. The tracking includes usage pattern analysis and comparing against a warranty requirement. Battery assessment is accomplished based on battery performance tracking across battery cells. A battery system comprising a plurality of battery cells is accessed, wherein the plurality of battery cells comprises a plurality of battery columns made up of battery cells arranged in series, wherein the plurality of battery columns is connected in parallel. The battery cells can include lithium-ion battery cells or other rechargeable battery cells. Information is obtained on a battery cell within the plurality of battery cells, wherein the battery cell information is obtained using near field communication (NFC). Further information can be obtained using a barcode, a QR code, and the like.

The information on the battery cell is tracked by a column controller for a battery column from the plurality of battery columns, wherein the battery cell resides within the battery column. The column controller includes a cluster controller for a group of the plurality of battery cells. The tracking includes usage pattern analysis and comparing against a warranty requirement. The information on the battery cell is stored for future reference. The storing the information on the battery cell is accomplished using blockchain technology. The information on the battery cell that was stored is analyzed. The analyzing the information includes recording regulatory information. The analyzing the information further includes evaluating performance against sustainability goals. The analyzing includes evaluating abnormal data that impacts a service level agreement (SLA). A capability metric for the battery cell is predicted based on the analyzing of the information on the battery cell. The capability metric includes voltage, power, energy, or number of cycles. The capability metric for the battery cell is aggregated with capability metrics from other cells from the plurality of cells, wherein the other cells reside within a same column as the battery cell for which the capability metric was predicted, to produce a column capability metric. The column capability metric is aggregated with capability metrics from other battery columns to produce a battery system capability metric. Information is obtained on a second battery cell within the same battery column as the battery cell, the information on the second battery cell is tracked, and a capability metric is predicted for the second battery cell.

In addition to managing new batteries and reused batteries, disclosed concepts enable managing the mixing of battery technology (e.g., lithium-ion batteries used in conjunction with sodium-ion batteries), the mixing of battery manufacturers, the mixing of various performance tier batteries, the mixing of various battery ratings, etc., all in a single or multiple battery application.

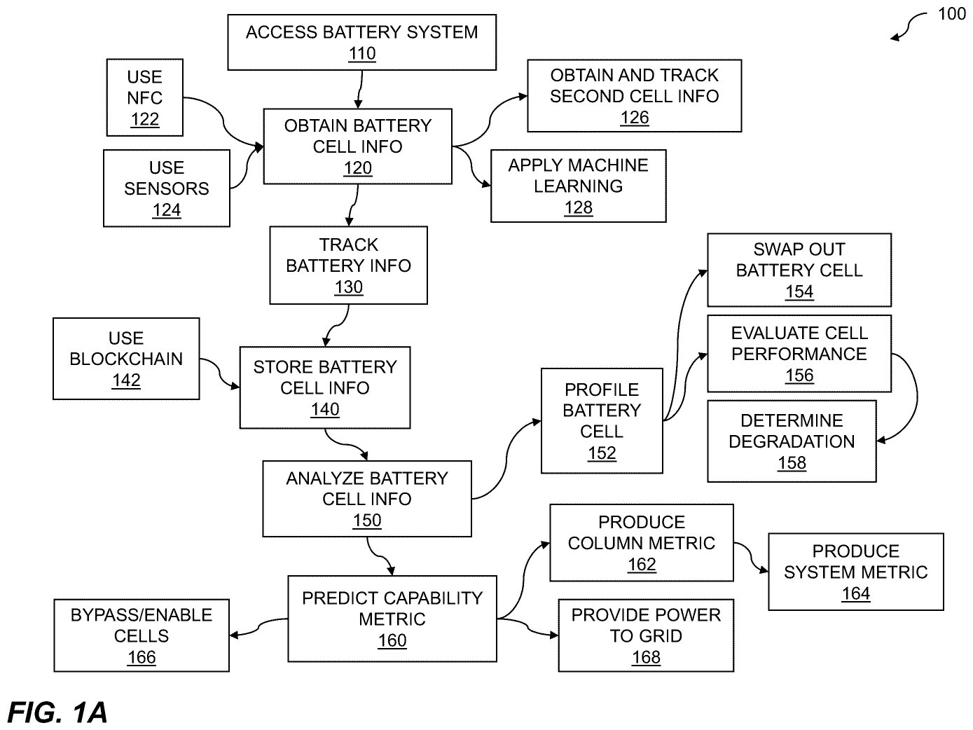

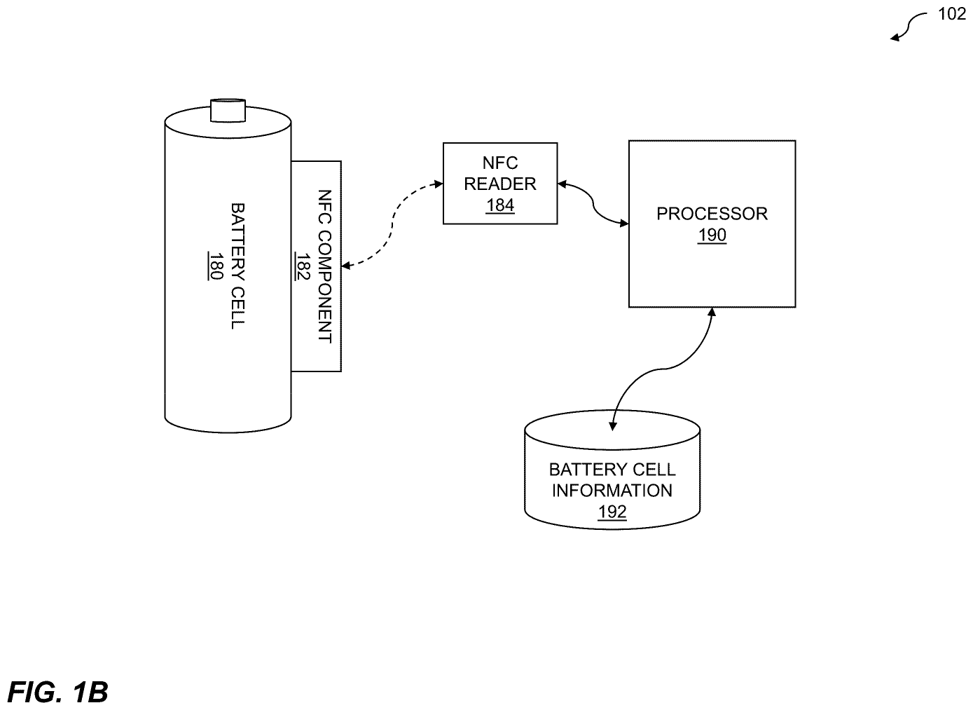

FIG. 1A is a flow diagram for battery performance tracking across battery cells. Batteries, such as rechargeable batteries used in electric vehicles, battery backup units, personal electronic devices, and so on, require replacement after a number of charge-discharge cycles or due to battery failure. In the former case, where the batteries have been charged and discharged as part of routine use, the batteries may no longer meet manufacturer or application specifications. The batteries can be removed and replaced as part of routine or preventative maintenance. The removed batteries, however, can still be capable of storing electrical energy and of providing the electrical energy in a variety of other applications, albeit with perhaps diminished capabilities. The second life batteries can be repurposed and reconfigured for use within a battery system. These “second life” batteries can be scanned to obtain information associated with battery performance, and the information can be analyzed to predict a capability metric for the battery cells. The capability metric can be used to predict battery usability and capacity. Based on this analysis, a battery system configuration that is based on the second life batteries can be determined. Battery units or columns, which are based on battery cells, can be coupled to form a battery system. The coupling is accomplished using switching components that are coupled to the battery cells. In addition to switches, scanners comprising switches can be coupled to the battery cells. These scanners can continually monitor the battery cells for performance and can further detect anomalous parameters such as overheating or substantially short-circuit impedance. Other information can be obtained using near-field communication to read an NFC tag, a scanner to read a barcode or quick response (QR) code, etc. Thus, the battery cells can be dynamically controlled for performance, safety, longevity, and so on.

The flow 100 includes accessing a battery system 110. The battery system comprises a plurality of battery cells, wherein the plurality of battery cells comprises a plurality of battery columns made up of battery cells arranged in series, wherein the plurality of battery columns is connected in parallel. The plurality of battery cells can include two or more battery cells. The battery cells can include homogeneous battery cells, heterogeneous battery cells, and so on. The battery cells can include substantially similar physical dimensions, a mixture of battery cells with substantially different physical dimensions, etc. The battery cells, which can include rechargeable battery cells, can include a variety of battery types. In embodiments, the one or more battery cells can include lithium-ion battery cells. Other types of rechargeable cells, such as sealed lead-acid (SLA), nickel-cadmium (NiCd), nickel-metal hydride (NiMH), lithium-polymer (LiPo), lithium-iron-phosphate (LiFePO4), sodium-ion, lithium-metal, solid-state, sodium ion, zinc based, etc., can be included. In embodiments, the battery cells in a battery column can include battery cells connected in series.

Further embodiments can include calculating a battery index for the column of battery cells. The battery index for the column of cells can be based on the “healthiness” of a battery cluster. In embodiments, the battery index for the cluster can include a health measure for the cluster. A health measure for the battery cluster can be based on a state of charge, operating temperature, internal impedance of a battery cell, etc. Embodiments can include calculating a decay rate for the battery index. The decay rate can be associated with a rate of change of the state of charge, the state of health, the internal temperature, the internal impedance, etc. In embodiments, the decay rate can include a rate of change for the battery index. The decay rate can be used to predict the end-of-life of a battery system, battery column, battery cell, etc. In a usage example, a rapid or accelerating decay rate can indicate that a battery system, column, or cell requires replacement, whereas a substantially stable decay rate can indicate remaining useful life in the battery system, column, or cell.

In embodiments, the rate of change can include a rate of change on state of charge for each battery cell. The rate of change of state of charge for a battery cell can indicate that the battery cell is less capable of holding a charge, has increased leakage, etc. In other embodiments, the rate of change can include a rate of change on state of health for each battery cell. The rate of change of state of health can include a battery cell reaching end of service, etc. In further embodiments, the rate of change can include a rate of change on temperature or impedance for each battery cell. An increase in battery cell temperature or a decrease in internal impedance can indicate that immediate management control is necessitated to remove the battery cell from service. Embodiments can include determining a battery cluster or column deterioration graph based on the decay rate for the battery index. The deterioration graph can be rendered as a graph or plot, an analog display, a digital display, etc. The deterioration graph can include a representation for maximum run-time voltage, power, or energy for the battery system.

Embodiments can include modifying battery management based on the decay rate that was calculated. The modifying battery management can include coupling an additional battery system, a battery column within a battery system, etc. The modifying management can include decoupling battery systems, columns, cells, and so on. The modifying can include recommending preplacement of a battery system, column, or cell. The modifying can include altering charge rates, discharge rates, etc. The modifying can include enabling or disabling cooling for a battery system. Embodiments can further include calculating a decay profile for the battery index based on the modified battery management. The decay profile can include metadata such as battery cell type, manufacturer, manufacturing date, in-service date, etc. The battery management modification discussed above can include one of a plurality of modifications to battery management. Embodiments can include correlating the decay profile to other decay profiles with alternate modifications to battery management. The correlating can be used to identify superior or preferred battery systems, battery cell failures associated with a manufacturer, and so on.

The flow 100 includes obtaining information 120 on a battery cell within the plurality of battery cells. The information on the battery can include a state of charge (SOC) for the battery cell. The state of charge can include a value such as a voltage, a percentage, a threshold, and so on. The information on the battery cell can include additional parameters, values, and so on. In embodiments, the information on the battery can include a state of health (SOH). The state of health information on the battery cell can include temperature, internal impedance, and the like. The temperature and internal impedance values can be used to determine whether the battery is operating within acceptable parameter ranges. If the battery is not operating within acceptable or safe parameters, then the battery can be quickly decoupled from the battery system and safely discharged. The battery cell can be swapped out, replaced, etc. In embodiments, the information on the battery cell can include a number of charge cycles and a number of discharge cycles. A battery cell can operate for a finite number of charge/discharge cycles. Information on the number of charge/discharge cycles can be used to predict remaining usefulness or viability of a battery cell.

In the flow 100, the battery cell information is obtained using near field communication (NFC) 122. NFC is a wireless communication protocol that can have an effective range of a few centimeters such as 4 cm. The NFC communication can be used to collect information from an NFC tag, NFC chip, etc. that can be coupled to the battery. In the flow 100, the information is obtained using built-in sensors 124 coupled to the battery cell. The sensors can include voltage, current, temperature, impedance sensors, etc. Other identifying markings, codes, etc., such as a barcode, quick response (QR) code, etc., can be coupled to the battery cell. The NFC tag, barcode, or QR code can also be used to track the battery cell subsequent to removal of the battery cell from a battery system. A signature can also be associated with the battery cell and can be used in conjunction with the NFC tag, barcode, QR code, etc. The NFC tag, barcode, QR code, etc. enable tracking of the battery cell from manufacture, through operation, through removal, through second life usage, through retirement, and through recycling.

The flow 100 further includes obtaining information on a second battery cell 126 within a same battery column as the battery cell, tracking the information on the second battery cell, and predicting a capability metric (described below) for the second battery cell. The second cell can include a battery cell substantially similar to the first battery cell or substantially different from the first battery cell. The second battery cell can include a battery cell that is presently in use, a spare cell, a backup cell, etc. Further embodiments include bypassing the battery cell and enabling the second battery cell, using software-controlled switches, based on the capability metric for the battery cell and the capability metric for the second battery cell. If the first battery cell is no longer performing adequately, is presenting to be near failure, etc., the second cell can be coupled to the battery column and the first battery cell can be bypassed, effectively removing it from the battery column. The flow 100 further includes applying machine learning 128 to changes in the information on the battery cell. The machine learning can be trained to monitor one or more battery cells, to predict when a battery cell is presenting anomalous behavior or nearing failure, etc. The machine learning can track battery cell usage, usage patterns, changes in usage, and so on. In embodiments, the machine learning evaluates charge/discharge cycles, source of energy, or battery system location.

The flow 100 includes tracking the information 130 on the battery cell by a column controller for a battery column from the plurality of battery columns, wherein the battery cell resides within the battery column. The tracking information on the battery cell can include tracking charge/discharge cycles, changes in battery cell usage patterns, anomalous behavior of one or more battery cells, and so on. In embodiments, the column controller can include a cluster controller for a group of the plurality of battery cells. The cluster can comprise two or more battery cells. The tracking can include location information. Embodiments can further include using location-based technology to track a location for the battery system. The tracking location can be used to confirm that an installed battery system is actually sited at the location where the system was installed. The tracking location can also track battery cell columns and battery cells. In embodiments, the tracking the information is accomplished for the battery cell over a life cycle for the battery cell. The tracking information can be associated with location of battery cell manufacture, present location of the battery cell, and so on. The tracking can confirm that a battery cell is in storage, has arrived at a recycling facility, etc. The controlling can be applied to the battery cells, columns, and battery system. In embodiments, the controlling the battery system can control the allocation of current intake to a subset of battery columns from the battery system during a charge event. Current intake can be associated with charging of battery cells and battery columns which are integrated into a battery system. The amount of current provided for current intake can be dependent on the type of rechargeable battery that is being recharged. In other embodiments, the battery system controls application of voltage coupled to the battery cells with battery columns during a charge event. Again, the control of application of voltage coupled to the battery cells can be based on the type of battery cells within the battery columns. In embodiments, the battery system can further control application of voltage applied to the subset of battery cells and battery columns. The application of voltage applied to the subset of battery units can vary over time.

The tracking the information on the battery cell can be used for battery system management, contract obligations, regulatory compliance, warranty service, and so on. Further embodiments include managing user contracts for the battery system based on the information for the battery cell that was tracked. A user contract can include an amount of voltage or current to be provided, reliability and availability requirements, redundancy, etc. In embodiments, the managing can include comparing a contracted amount versus an available amount based on a capability metric (described below). In other embodiments, the tracking can include usage pattern analysis and comparing against a warranty requirement. Recall that a finite number of charge/recharge cycles can be associated with a battery cell. If usage of the battery cell increases, necessitating an increase in the number of charge/discharge cycles, then the battery cell can reach an end-of-life state sooner than if the battery cell were used less. Since a warranty can specify battery replacement within a time period, then the battery cell is more likely to require replacement, thereby activating the warranty. In embodiments, the tracking the information on the battery cell is performed over time to determine a change in performance of the battery cell.

The flow 100 includes storing 140 the information on the battery cell for future reference. The storing the information can be accomplished using local storage associated with a column control, a battery system, etc. The storing the information can further be accomplished using storage on site with the battery system, remote storage, cloud-based storage, and so on. The information on the battery can be stored in clear text, in an encrypted format, in a trackable format, and the like. In the flow 100, the storing the information on the battery cell is accomplished using blockchain technology 142. Blockchain technology, which can include a distributed digital ledger technique, can be used to track and verify all transactions associated with a battery cell. The transactions can include manufacture of the battery cell, purchaser, battery system in which the battery cell is installed, and so on. The blockchain can further include information associated with in-service and removed-from-service dates, recycling information, etc.

The flow 100 includes analyzing 150 the information on the battery cell that was stored. The analyzing can include descriptive analysis, diagnostic analysis, inferential analysis, predictive analysis, causal analysis, and so on. In embodiments, the analyzing the information can include recording regulatory information. The regulatory information can include a maximum amount of energy storage based on the site of the battery system, the location of the battery system, fire detection compliance, etc. In other embodiments, the analyzing the information can include evaluating performance against sustainability goals. The source of energy that can be used to charge the battery system can include grid power, renewable power, and so on. In embodiments, the source of energy can include a green energy source. Various types of renewable and green energy sources can be used for charging the battery system. In embodiments, the green source can include a photovoltaic, wind, or thermal source. Depending on the location of the battery system, green energy sources can include geothermal, wave-action, etc. The “quality” or benefit received from using the green energy source can be determined. In embodiments, a quantification number can be calculated for an amount of carbon saved based on the green energy source. The quantification number can include a value, a percentage, a threshold, and the like. In other embodiments, the analyzing can include evaluating abnormal data that impacts a service level agreement (SLA). The abnormal data can indicate that a service call should be scheduled, that one or more battery cells require replacement, etc.

The flow 100 further includes profiling the battery cell 152, in comparison to other battery cells within the plurality of battery cells, to produce a battery cell profile. A battery profile can include usability data, remaining capacity data, and other data associated with a battery cell. In embodiments, the profiles can include information on aging, brand, or specification. The profiles can further include manufacturing date; batch number; serial number; in-service date; removed-from-service date; notations about observed wear, cracks, or damage; etc. The profiles can be uploaded by a user, downloaded from a library or repository, and so on. The profiles can be determined while the battery units are in use. The flow 100 further includes swapping out the battery cell 154 based on the battery cell profile. A battery cell can be swapped out for a variety of reasons such as diminished storage capacity, physical damage, operating temperature over a safety threshold, internal cell impedance too low (e.g., a substantially short circuit), etc., and other data that can be associated with the battery cell profile. In addition, newly manufactured batteries, even from the same manufacturer, can have different usage characteristics and therefore different profiles. Thus, new batteries, new batteries with reduced specifications, reused batteries, etc. can each have disparate performance characteristics and can require different profiles. While disparate batteries can include different performance characteristics for a given battery type, such as lithium-ion batteries from different manufacturers, with different performance characteristics, with different aging and use profiles, etc., disparate batteries can also include different battery types, such as mixing lithium-ion batteries with lithium-metal batteries or mixing lithium-ion batteries with sodium-ion batteries in a battery system. The mixing can include both serial connections and parallel connections of disparate batteries and disparate battery types.

The flow 100 further includes evaluating performance 156 of the battery cell in comparison to other battery cells within the plurality of battery cells. Since the battery cells within the plurality of battery cells can be second-life batteries, the performance of the battery cells can be expected to be lower than when the battery cells were manufactured. However, a battery cell that compares poorly with the other battery cells can cause charge leakage, overheating, and other potentially dangerous situations. The flow 100 further includes determining a degradation 158 in performance of the battery cell over time based on the evaluating. The determining degradation in performance can be used to determine a routine maintenance schedule, planned battery cell replacement, etc.

The flow 100 includes predicting a capability metric 160 for the battery cell based on the analyzing of the information on the battery cell. The capability metric can include an ability of a battery cell to store and deliver charge, a leakage factor, remaining service life, and so on. A capability metric can be predicted for an individual battery cell, a cluster of battery cells, a column of battery cells, battery cells within a battery system, etc. In embodiments, the capability metric can include voltage, power, energy, or number of cycles. The capability metric can further include manufacturer, chronological age, etc. The flow 100 further includes aggregating the capability metric for the battery cell with capability metrics from other cells from the plurality of cells, wherein the other cells reside within a same column as the battery cell for which the capability metric was predicted, to produce a column capability metric 162. The column capability metric can be based on a sum of battery cell metric, an average of metrics, a weighted sum of metrics, and so on. The flow 100 further includes aggregating the column capability metric with capability metrics from other battery columns to produce a battery system capability metric 164. The battery system capability metric can be based on a sum, an average, etc.

The flow 100 can further include bypassing the battery cell and enabling the second battery cell 166, as discussed previously. The bypassing and enabling can be necessitated by battery cell diminished capability or failure, having reached its service end of life, and so on. The bypassing the battery cell and enabling the second battery cell can be accomplished using software-controlled switches, based on the capability metric for the battery cell and the capability metric for the second battery cell. The software-controlled switches can include smart switches. The predicted capability for the battery cell can be used to achieve other goals associated with energy storage and delivery. Further embodiments include performing energy trading based on the capability metric for the battery cell. The energy trading can include purchasing and storing energy when energy prices are relatively low, then providing energy when energy prices are relatively high. The flow 100 further includes providing power from the battery system to a power grid 168 based on the capability metric. The capability metric can be used to minimize the risk of over-discharging the battery system which would force otherwise unnecessary additional charge/discharge cycles, etc. In a usage example, an individual energy consumer installs a battery system at their premises. The consumer pays for energy to charge the battery system, then is able to draw energy from the battery system during a power outage. In addition, during peak energy demand periods, an energy supplier such as an electrical utility can withdraw energy from the consumer's battery system. The electrical utility pays the consumer for the extracted energy based on net metering. Various steps in the flow 100 may be changed in order, repeated, omitted, or the like without departing from the disclosed concepts. Various embodiments of the flow 100 can be included in a computer program product embodied in a non-transitory computer readable medium that includes code executable by one or more processors.

FIG. 1B is a block diagram showing NFC protocol usage. Discussed previously and throughout, information on a battery can be obtained. The information can be obtained from the battery cell using a scanner or sensor, by reading a tag such as a barcode or quick response (QR) code, and so on. The information can be obtained using a wireless communication technique such as near-field communication (NFC). The use of NFC for obtaining battery information enables battery performance tracking of battery information across battery cells. A battery system comprising a plurality of battery cells is accessed, wherein the plurality of battery cells comprises a plurality of battery columns made up of battery cells arranged in series, wherein the plurality of battery columns is connected in parallel. Information on a battery cell within the plurality of battery cells is obtained, wherein the battery cell information is obtained using near field communication (NFC). The information on the battery cell is tracked by a column controller for a battery column from the plurality of battery columns wherein the battery cell resides within the battery column. The information on the battery cell is stored for future reference. The information on the battery cell that was stored is analyzed. A capability metric for the battery cell is predicted based on the analyzing of the information on the battery cell.

A block diagram for NFC protocol usage is shown 102. Near-field communication, or NFC, is a wireless communication protocol that is useful for sending information between electronic devices over short distances. A short distance can include substantially 4 centimeters (4 cm). A battery cell 180 can include a battery cell within a battery column, a battery system, and so on. An NFC component 182 can include an NFC tag, an NFC chip, etc. that can be coupled to the battery. Other identifying markings, codes, etc., such as a barcode or quick response (QR) code, can be coupled to the battery cell, etc. The NFC tag, barcode, or QR code can also be used to track the battery cell subsequent to removal of the battery cell from a battery system. A signature can also be associated with the battery cell and can be used in conjunction with the NFC tag, barcode, QR code, etc. The NFC tag, barcode, QR code, etc. can enable tracking of the battery cell from manufacture, through operation, through removal, through second life usage, through retirement, and through recycling. An NFC enabled device or NFC reader 184 can be used to read data such as battery information data from the NFC component. The data can be read wirelessly by the NFC reader. The data that can be read can include a number of charge cycles, a number of discharge cycles, a source of energy used to charge the battery cell, and so on. The NFC reader can be coupled processor 190. The processor can include a computer, a handheld device, a processor core within an integrated circuit or chip, etc. The processor can be used to configure, control, or otherwise manipulate the NFC reader. Battery information associated with battery cells can be stored 192 for future reference. The storage can include storage coupled to the processor, remote storage, cloud-based storage, etc.

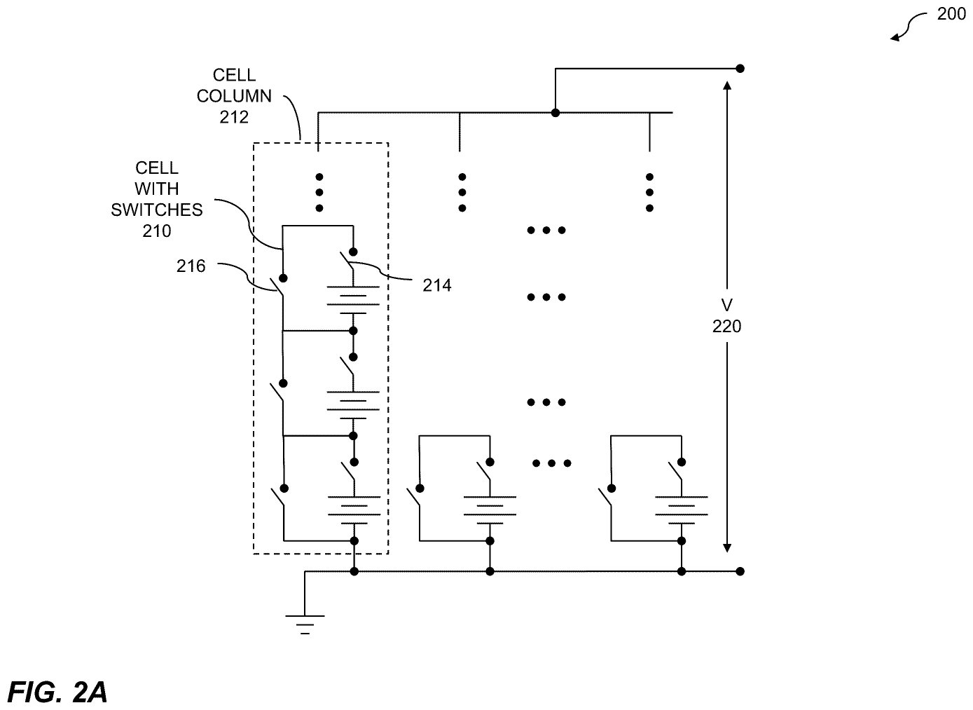

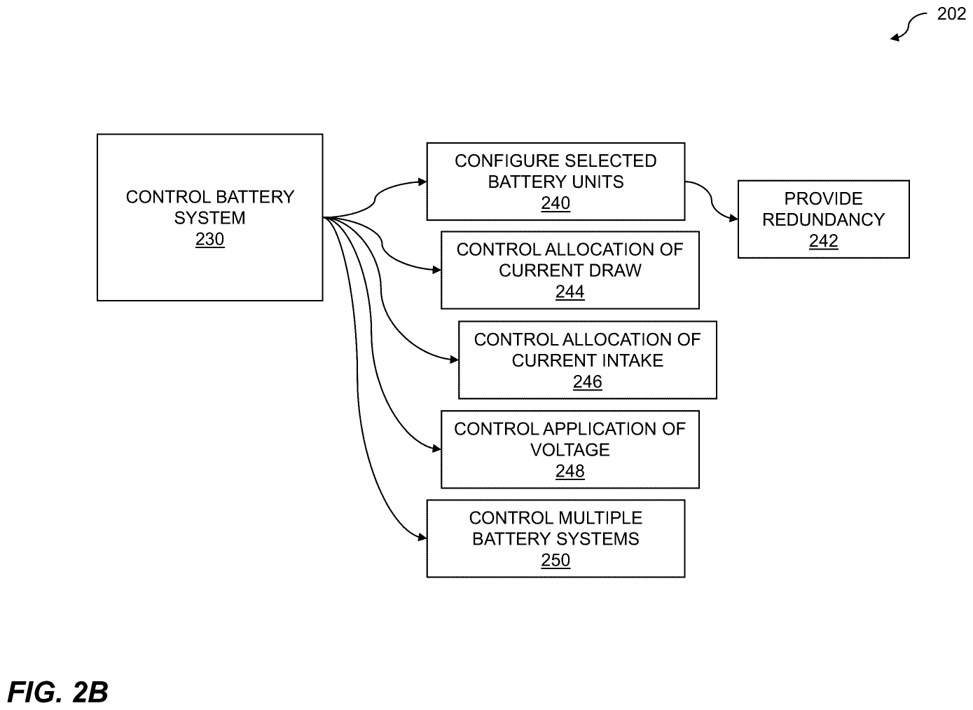

FIG. 2A illustrates columns of battery cells and switches in a battery system. Discussed above and throughout, clusters of battery cells can be grouped into battery columns, and battery columns can be grouped into a battery system. An individual battery cell can be coupled to or decoupled from a battery column of which the cell is a component. Similarly, a battery column can be coupled to or decoupled from a battery system. The decoupling can be accomplished by bypassing the battery cell, the battery column, etc. The coupling and bypassing can be accomplished using high-speed switches such as high-speed smart switches. The smart switches enable battery performance tracking across battery cells. A battery system comprising a plurality of battery cells is accessed, wherein the plurality of battery cells comprises a plurality of battery columns made up of battery cells arranged in series, wherein the plurality of battery columns is connected in parallel. Information on a battery cell within the plurality of battery cells is obtained, wherein the battery cell information is obtained using near field communication (NFC). The information on the battery cell is tracked by a column controller for a battery column from the plurality of battery columns, wherein the battery cell resides within the battery column. The information on the battery cell is stored for future reference. The information on the battery cell that was stored is analyzed. A capability metric is predicted for the battery cell based on the analyzing of the information on the battery cell.

A battery system comprising battery cells and switches is illustrated 200. The battery system can include one or more columns of grouped battery cells such as battery column 212. The battery columns can include one or more battery cells such as battery cell 210. In embodiments, the cluster of battery cells in a battery column includes battery cells connected in series. Each battery cell within a battery column can be coupled to or decoupled from the battery column using switches. The switches, such as switch 214 and switch 216 can accomplish coupling and decoupling respectively. In embodiments, the switches can include smart switches. A battery cell can be coupled to or grouped with other battery cells to form a battery column. A battery cell can be decoupled from a battery column if the battery cell is unneeded, is performing poorly, has failed, and so on. In embodiments, the decoupling can accomplish the bypassing a battery cell. Similarly, a battery column within a battery system can be coupled to or decoupled from the battery column. As for an individual battery cell, the decoupling can accomplish bypassing a battery column. The coupling switches and the bypass switches can be controlled by a controller component of a battery management system. The battery management system (discussed below) can measure the state for each battery cell, and can determine whether a battery cell is usable, available, and required by the system. The battery management system can control the switches associated with the battery cells and battery columns to enable cells and columns, to bypass cells and columns, etc. The battery cells within the battery columns can produce a voltage V 220. The voltage can be based on increments of voltage, where an increment of voltage can be determined by a voltage associated with a battery cell.

FIG. 2B is a flow diagram for battery system control. Batteries included within a disparate battery system can be controlled. Rechargeable batteries such as lithium-ion batteries that have been removed from vehicles, energy storage devices, personal electronic devices, and so on can be reused for other applications. These batteries can be considered used, previously used, preowned, “second life”, second hand, or can be described with some other terminology denoting a second usage. Such batteries can be well capable of functioning in certain capacities and usages. While the batteries may no longer meet their original specifications with respect to energy storage, leakage, and so on, the batteries can still store and provide energy. In order to use such “second life” batteries, the batteries can be disassembled down to their battery cells. Switches and scanners or sensors can be coupled to the battery cells. The switches can be used to couple, decouple, and bypass the battery cells, while the scanners and sensors can be used to monitor battery performance information such as temperature and/or temperature rate of change, current, voltage and/or voltage rate of change, or impedance data. The switches, which are based on high-speed switching devices, and the scanners can be controlled in order to operate the battery cells, battery units, and battery systems at their most efficient and safest levels. The safe battery levels can be monitored by a failsafe system that monitors safe battery levels and selectively disconnects battery units from the battery system before a battery unit failure. The battery cells, units, and systems can be monitored frequently in order to quickly respond to any detected problems. The monitoring and response enable battery performance tracking across battery cells.

The flow 202 includes controlling 230 the battery system. The controlling the battery system can include scanning battery units, where battery units contain one or more battery cells. The control can further include analyzing battery units to determine usability and capacity of the battery units. The controlling can include coupling or decoupling battery cells within battery units to the battery units, coupling or decoupling battery units within a battery system, coupling or decoupling battery systems within a plurality of battery systems, and so on. The controlling can collect battery unit performance information from the battery units. In the flow 202, the controlling the battery system can configure 240 selected battery units. Selected battery units can include battery units that have been identified based on the analyzing to have sufficient usability and capacity, such as storage capacity, to be used within a battery system. In the flow 202, the configuring the selected battery units provides redundancy 242 for the battery system. The redundancy can be based on storage capacity, battery system reliability, a backup power requirement, a safety factor, and so on. In embodiments, redundancy can be accomplished using an extra number of battery units in a column of battery units. The extra battery units can be switched in as needed to replace exhausted battery units, failed battery units, etc. In embodiments, the redundancy can provide for maintaining capacity. Capacity, such as storage capacity, can be maintained by switching in additional battery units as needed. Battery units can be switched in, switched out, bypassed, and so on. In other embodiments, the redundancy can provide for increasing reliability of the battery system. The redundancy can be based on N+1 redundancy, where N is the number of battery units required by a battery system plus one spare. The spare can be switched in as needed. Another redundancy scheme can include 2 N redundancy.

In the flow 202, the controlling the battery system controls allocation 244 of current draw from a subset of battery units from the plurality of battery units during a discharge event. The discharge event can include providing current to one or more loads. The discharge event can be based on providing constant voltage or constant current. In other embodiments, a discharge event can include a safety discharge event. A safety discharge event can occur when a battery cell or battery unit has failed, overheated, etc. The battery unit or cell can be safely discharged in order to avoid risk of fire or explosion in the battery unit or cell. In the flow 202, the controlling the battery system controls the allocation of current intake 246 to a subset of battery units from the plurality of battery units during a charge event. Current intake can be associated with charging battery cells, battery units, and a battery system. The charging of batteries can be based on providing constant current, variable current, constant voltage, variable voltage, etc. In embodiments, the battery system controls application of voltage 248 coupled to the subset of battery units from the plurality of battery units during a charge event. A technique used for the charging of batteries can be selected based on battery type. In the flow 202, the battery system further comprises controlling multiple connected battery systems 250. The multiple connected battery systems can be controlled by connecting or disconnecting one or more battery systems to maintain capacity, to provide redundancy, etc. Various steps in the flow 202 may be changed in order, repeated, omitted, or the like without departing from the disclosed concepts. Various embodiments of the flow 202 can be included in a computer program product embodied in a non-transitory computer readable medium that includes code executable by one or more processors.

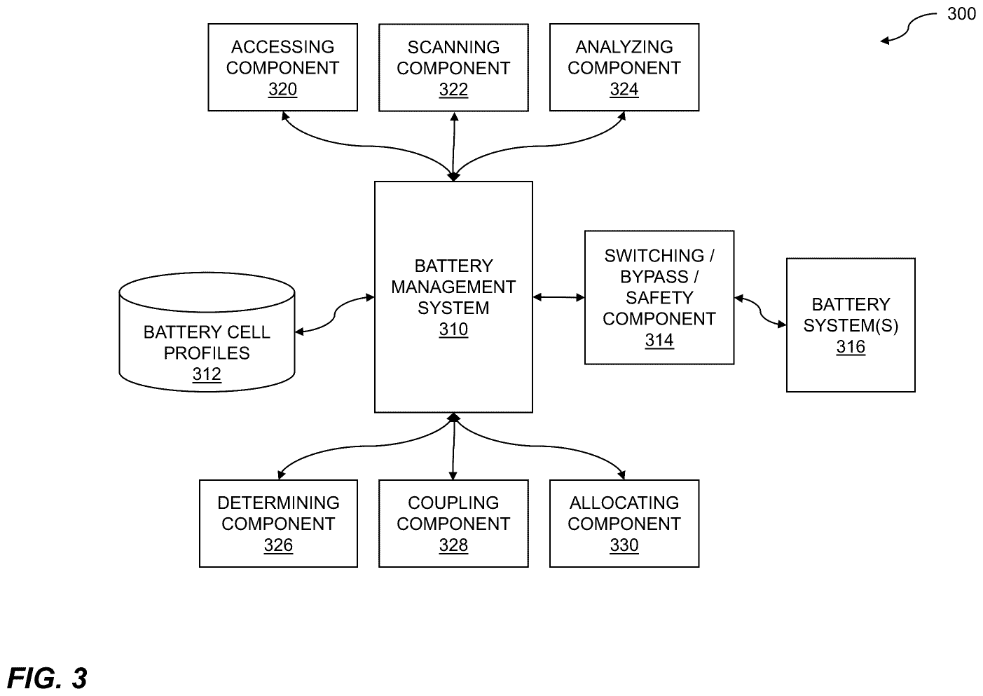

FIG. 3 is a system block diagram for dynamic battery system management. Discussed previously, dynamic battery control within a battery system can be accomplished at the battery cell level. This fine-grained level of control is based on obtaining, tracking, and analyzing performance information associated with the battery cells. The battery cells are continually monitored for present voltage and charge states, for cell health, and so on. The dynamic battery control enables a battery system to deliver a configured voltage, current, and the like. The dynamic battery control enables battery performance tracking across battery cells. A battery system comprising a plurality of battery cells is accessed, wherein the plurality of battery cells comprises a plurality of battery columns made up of battery cells arranged in series, wherein the plurality of battery columns is connected in parallel. Information on a battery cell within the plurality of battery cells is obtained, wherein the battery cell information is obtained using near field communication (NFC). The information on the battery cell is tracked by a column controller for a battery column from the plurality of battery columns, wherein the battery cell resides within the battery column. The information on the battery cell is stored for future reference. The information on the battery cell that was stored is analyzed. A capability metric for the battery cell is predicted based on the analyzing of the information on the battery cell.

The system block diagram 300 includes a battery management system 310. The battery management system can initiate scanning of battery units to determine one or more profiles for one or more battery cells within a battery unit. The battery management system can further analyze the battery units to determine whether a battery unit is usable for a given battery application, to determine the capacity of the battery unit to obtain and retain a charge, to ascertain the capacity of the battery to provide current, etc. The controller can be used to configure a battery system. In embodiments, the controlling the battery system can configure selected battery units to provide redundancy for the battery system. The redundancy can be used to increase battery uptime, to improve safety, etc. The controller can be used to swap out battery units. In embodiments, a battery unit within the plurality of battery units can be hot-swappable. The system block diagram includes battery cell profiles 312. The battery cell profiles can include a wide range of information associated with one or more of the battery units being used. In embodiments, the battery cell profiles can include usability and remaining capacity for battery units within the plurality of battery units. The usability information associated with the battery profile can be used to determine whether a battery unit can be chosen for inclusion within a battery system. The battery capacity can be used to determine how much current a battery element can provide, whether the battery unit requires recharging, whether the battery unit should be swapped out, etc. In embodiments, the battery profiles can be updated at any regular time interval. The regular time interval can be determined based on a safety factor such as rapid detection of an overheating battery cell in order to prevent fire or explosion. In embodiments, the building the profiles is accomplished using machine learning or statistical analysis.

The system block diagram 300 includes a switching, bypass, and safety (SBS) component 314. The SBS component can couple or decouple battery systems, battery units, battery cells, and so on. The SBS component can further enable bypassing of a battery system, one or more battery units with a system, one or more battery cells within a battery unit, etc. The SBS can be used to accomplish a failsafe system associated with the battery system. In embodiments, the failsafe system can monitor safe battery levels and can selectively disconnect battery units from the battery system before a battery unit failure. Levels associated with a battery system can be monitored by the battery management system. In embodiments, the safe battery levels can be based on voltage, current, or temperature. The battery levels can further be based on battery impedance. In a usage example, a battery with an impedance less than a nominal impedance can be nearing failure. Thus, the low impedance or short circuit can be detected, and the offending battery unit or battery cell can be switched out quickly. In embodiments, the failsafe system can be based on machine learning. The system block diagram includes one or more battery systems 316. The one or more battery systems can be configured to provide a voltage, an amount of current, a storage capacity, and the like. When more than one battery system is configured, the battery systems can be configured with redundancy. Discussed previously, a battery system can be formed by coupling battery units.

The battery management system 310 can be coupled to one or more components that can perform operations, obtain data, and so on. The block diagram 300 can include an accessing component 320. The accessing component can access a plurality of battery units. The battery units can be based on rechargeable batteries such as lithium-ion batteries. The battery units can contain one or more battery cells, where the battery cells may have a variety of profiles. The battery profiles can be built using machine learning. The battery profiles can include details about a given battery unit. In embodiments, the battery profiles can include usability and remaining capacity for battery units within the plurality of battery units. The battery profiles are not static, but rather can be updated at any regular time interval. The time interval can include a few milliseconds, seconds, etc. In embodiments, the profiles include information on one or more of the battery units being used.

The system block diagram 300 includes a scanning component 322. The scanning component can scan battery units within the plurality of battery units. The scanning can be used to collect performance information associated with the battery units. The performance information can include various types of data associated with the battery units. In embodiments, the performance information can include temperature, current, voltage, or impedance data. The performance data can be collected prior to configuring a battery system, while a battery system is in use, and so on. In embodiments, the performance information can be collected in real time during runtime. The system block diagram 300 includes an analyzing component 324. The analyzing component can be used to analyze the battery units to determine usability and capacity based on the performance information. The usability and capacity data can be included in the battery profiles. The usability data can include whether a battery unit is available for configuration in a battery system, whether the battery unit has physical integrity, etc. The capacity data of the battery unit can include remaining capacity. The remaining capacity can be based on a percentage, a value, a threshold, and so on.

The system block diagram 300 includes a determining component 326. The determining component can be used to determine a battery system configuration based on the analyzing. The battery system configuration can be based on a quantity of battery units; a required voltage, current, and storage capacity; a required redundancy level; a safety margin; and so on. In embodiments, the determining the battery system configuration can be further based on profiles of the battery cells. The system block diagram 300 includes a coupling component 328. The coupling component can be used to couple battery units within the plurality of battery units to form a battery system, wherein the coupling is accomplished by switching based on the determining. In embodiments, fast-switching technology can be used to connect or disconnect one or more of battery units from the battery system. The switching technology can further be used to bypass one or more battery cells, battery units, and so on. In embodiments, the fast-switching technology can include isolated-gate transistor technology. The system block diagram 300 can include an allocating component 330. The allocating can include allocation of current, application of voltage, and so on. The allocating can be based on the controlling. In embodiments, the controlling the battery system can control allocation of current draw from a subset of battery units from the plurality of battery units during a discharge event. A discharge event can include normal operation of the battery system where current can be provided to one or more loads. The discharge event can also occur due to a battery failure, overheating, etc. In embodiments, a discharge event can include a safety discharge event. A battery can be safely discharged in order to prevent or reduce the risk of battery explosion, the battery catching fire, and so on. In other embodiments, the controlling the battery system can control the allocation of current intake to a subset of battery units from the plurality of battery units during a charge event. The controlling the current intake can be based on the type of rechargeable batteries that are to be recharged.

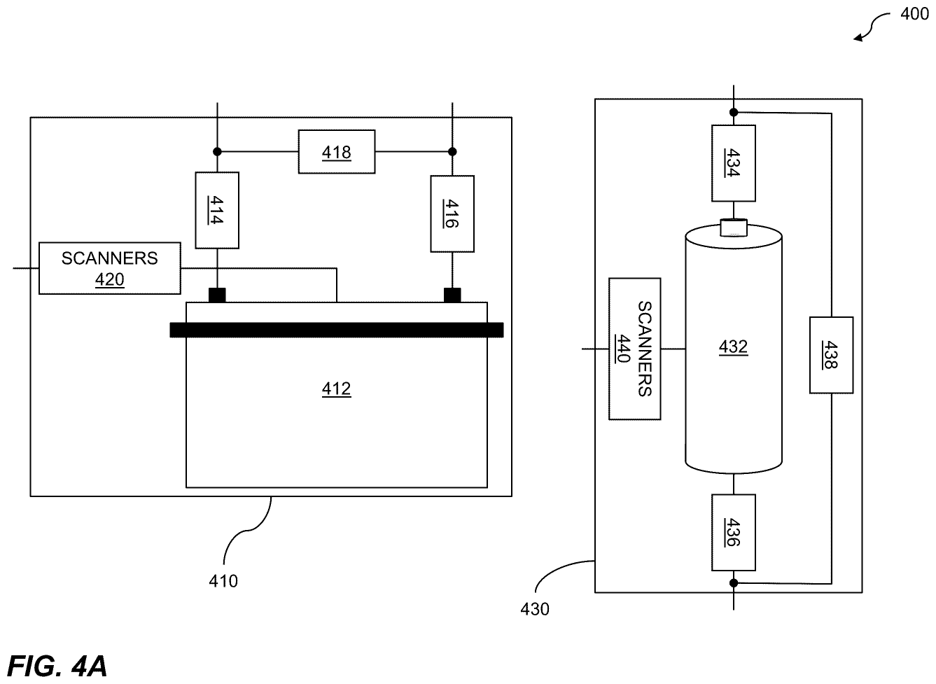

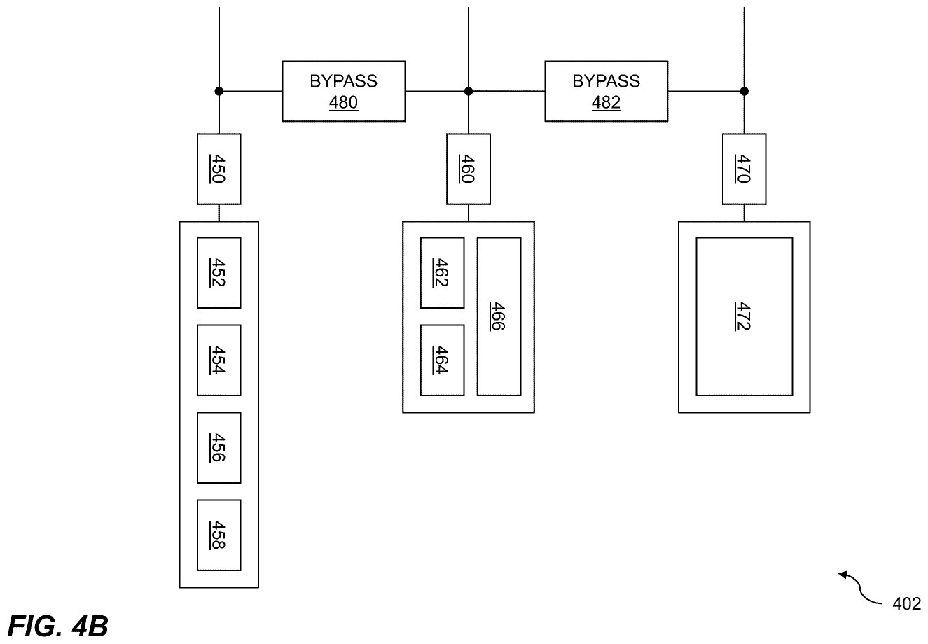

FIG. 4A illustrates example battery units. One or more battery units, each of which can comprise one or more battery cells, can be used as building blocks for a battery system configuration. A battery unit can include a battery column. A battery unit can further include switches, sensors, monitors, and so on. The switches and sensors can be used to select, bypass, and control a battery unit; to monitor the condition, state of charge, and state of health of a battery unit; and so on. The switching and sensing of the battery unit enables battery performance tracking across battery cells. A system comprising a plurality of battery cells is accessed, wherein the plurality of battery cells comprises a plurality of battery columns made up of battery cells arranged in series, wherein the plurality of battery columns is connected in parallel. Information on a battery cell within the plurality of battery cells is obtained, wherein the battery cell information is obtained using near field communication (NFC). The information on the battery cell is tracked by a column controller for a battery column from the plurality of battery columns, wherein the battery cell resides within the battery column. The information on the battery cell is stored for future reference. The information on the battery cell that was stored is analyzed. A capability metric is predicted for the battery cell based on the analyzing of the information on the battery cell.

Two example battery unit configurations are illustrated 400. A battery unit configuration 410 shows a battery 412 with top-mounted terminals. The top-mounted terminals can include binding posts, lugs, bolts, screws, etc. The battery 412 can be coupled to one or more switches such as switches 414 and 416. In some configurations, one of the switches 414 or 416 may be eliminated in order to enable a common ground, a common positive, and so on. The battery unit 410 can include a bypass switch such as switch 418. The bypass switch can be used to bypass the battery 412. The bypassing of the battery can be used to swap out a battery, to eliminate a failed or overheated battery, etc. The battery unit 410 can further include one or more scanners 420. The one or more scanners, which can be based on one or more sensors, can determine one or more levels associated with the battery 412. The levels associated with the battery 412 can include safe battery levels. In embodiments, the safe battery levels can be based on voltage, current, temperature, open circuit voltage, battery cell impedance, etc. The scanners can include standalone components or can be incorporated into one or more other components associated with the battery unit. In embodiments, the scanners can be colocated with the bypass switch 418. A second battery unit configuration 430 is shown. The second battery unit configuration shows a battery 432 with a different terminal configuration from that of the first battery 412. The second battery unit configuration can further include selection switches 434 and 436, and a bypass switch 438. The battery unit 430 can additionally include scanners 440. As was the case for the scanners and bypass switch associated with the first battery unit 410, in embodiments, the scanners 440 can be colocated with the bypass switch 438.

FIG. 4B illustrates multiple battery unit configurations. A battery unit can include a battery column. A battery column can include one or more battery cells, where the cells can include cells with varying terminal configurations, sizes, weights, and so on. The battery cells within a battery unit can include a substantially similar battery type. In embodiments, the one or more battery cells can include lithium-ion battery cells. Other battery types that can be used within a battery unit can include sealed lead-acid (SLA), nickel-cadmium (NiCd), nickel-metal hydride (NiMH), lithium-polymer (LiPo), lithium-iron-phosphate (LiFePO4), sodium-ion, lithium-metal, etc. The battery cells within a battery unit can be selected, bypassed, etc. using one or more switches. The switches can include smart switches. The multiple battery unit configurations enable battery performance tracking across battery cells. Multiple battery unit configurations are shown 402, where one or more battery units can be configured to form a battery system. The multiple battery units can include switches associated with battery cells. The battery units can include a switch 450 associated with battery cells 452, 454, 456, and 458; a switch 460 associated with battery cells 462, 464, and 466; a switch 470 associated with battery cell 472, and so on. A battery unit can be bypassed using one or more bypass switches such as bypass switch 480 and bypass switch 482.

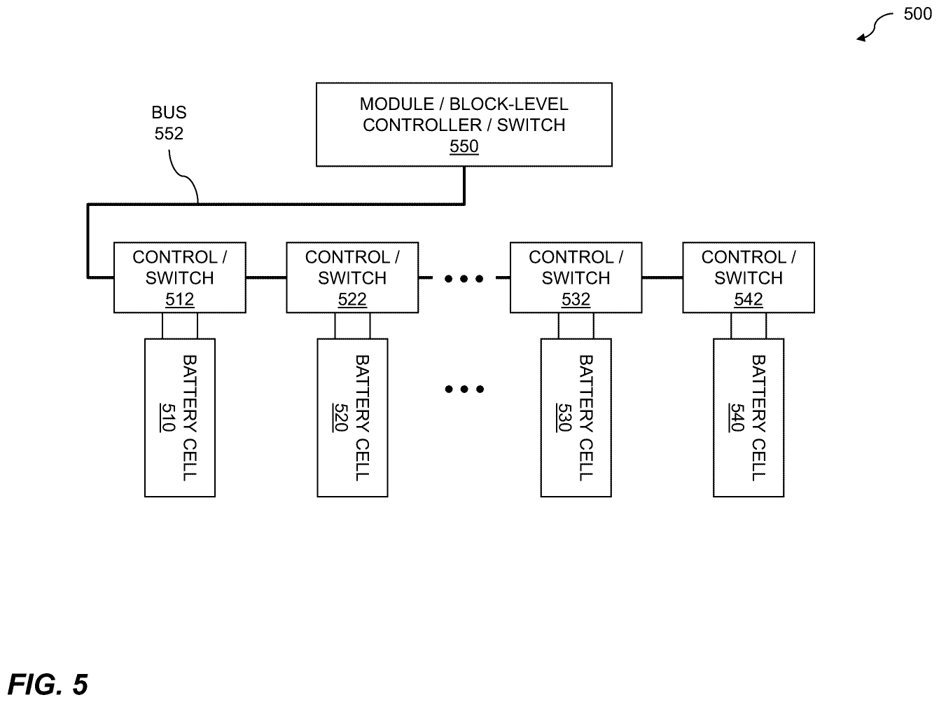

FIG. 5 is a system schematic diagram for battery management. Described above and throughout, battery cells can be grouped to form battery columns, and battery columns can be grouped to form a battery system. The battery system can be controlled to couple and decouple battery units, to charge the battery units, to control discharge of the battery units, and so on. The coupling and decoupling of the battery units is accomplished by switching that is controlled by battery management using smart switches. The battery management enables battery performance tracking across battery cells. A battery system comprising a plurality of battery cells is accessed, wherein the plurality of battery cells comprises a plurality of battery columns made up of battery cells arranged in series, wherein the plurality of battery columns is connected in parallel. Information on a battery cell within the plurality of battery cells is obtained, wherein the battery cell information is obtained using near field communication (NFC). The information on the battery cell is tracked by a column controller for a battery column from the plurality of battery columns, wherein the battery cell resides within the battery column. The information on the battery cell is stored for future reference. The information on the battery cell that was stored is analyzed. A capability metric is predicted for the battery cell based on the analyzing of the information on the battery cell.

The system block diagram 500 includes a battery cell 510. The battery cell can be associated with one of a variety of profiles, where the profiles can include usability, remaining capacity, and so on. The battery cell can be associated with a type of rechargeable battery. In embodiments, the battery cell can include a lithium-ion battery. Other types of rechargeable batteries can include sealed lead-acid (SLA), nickel-cadmium (NiCd), nickel-metal hydride (NiMH), lithium-polymer (LiPo), lithium-iron-phosphate (LiFePO4), sodium-ion, lithium-metal, etc. One or more battery cells can be coupled together to form a battery unit. A battery cell can further be characterized based on voltage, energy storage, size, weight, terminal configuration, and the like. The system block diagram includes a control and switch component 512. The control and switch component can be used to control access to the battery cell to enable charging of the cell and discharging of the cell (e.g., using the cell to provide current). The control and switch component can couple the battery cell to a battery unit, can decouple the battery cell from the battery unit, etc. The control and switch component can further include one or more sensors. The sensors can include current, voltage, temperature, and impedance sensors. The control and switch component can be used to bypass a battery cell in the event that the cell is unneeded, has failed, has overheated, etc. The system block diagram 500 can include further battery cells and further control and switch components such as battery cell 520 and control and switch component 522; battery cell 530 and control and switch component 532; and battery cell 540 and control and switch component 542.

The system block diagram includes a module/block-level controller and switch 550. The module/block-level controller and switch (MBCS) can select which battery cells can be included in a battery unit, can bypass one or more battery cells, and the like. The battery cells and their associated controller/switches can be configured in arrays comprising one or more rows, one or more columns, etc. The MBCS can communicate with the one or more battery cells and associated controllers using a bus 552. One or more battery units can be configured to form a battery system. In embodiments, the controlling the battery system can configure selected battery units to provide redundancy for the battery system. The redundancy can be based on providing additional battery cells, battery units, battery systems, etc. In embodiments, the redundancy can be accomplished using an extra number of battery units in a column of battery units. Recall that one or more battery cells can be coupled to or decoupled from a battery unit. Battery cells can further be bypassed. Further embodiments include bypassing one or more battery units in the column based on the extra number. The bypassing can be accomplished using fast-switching technology to connect or disconnect one or more of battery units from the battery system. In embodiments, the fast-switching technology can include isolated-gate transistor technology.

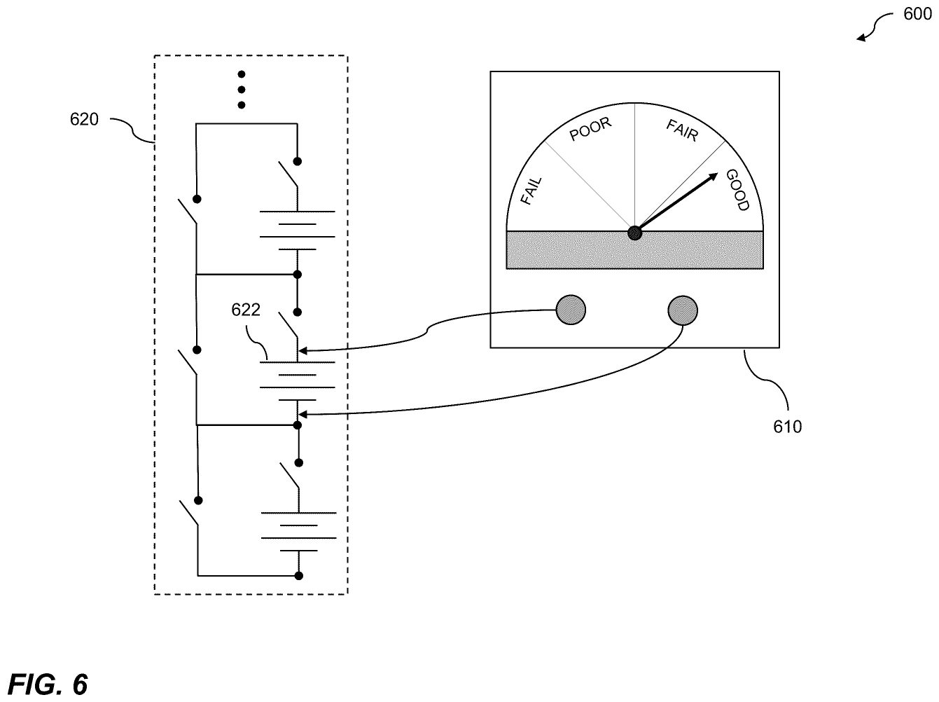

FIG. 6 illustrates a battery system index gauge. A battery index for a battery system can be calculated based on information obtained on a battery cell. The battery cell information can include a measured state for each battery cell. The measured state can include a state of charge for each battery cell, a state of health for each battery cell, and so on. A battery system index gauge can indicate one or more states associated with a battery cell within a battery system. The calculated index can be rendered on a battery index gauge. The battery index gauge enables battery performance tracking across battery cells. A battery system comprising a plurality of battery cells is accessed, wherein the plurality of battery cells comprises a plurality of battery columns made up of battery cells arranged in series, wherein the plurality of battery columns is connected in parallel. Information on a battery cell within the plurality of battery cells is obtained, wherein the battery cell information is obtained using near field communication (NFC). The information on the battery cell is tracked by a column controller for a battery column from the plurality of battery columns, wherein the battery cell resides within the battery column. The information on the battery cell is tracked for future reference. The information on the battery cell that was stored is analyzed. A capability metric is predicted for the battery cell based on the analyzing of the information on the battery cell.

A battery system index gauge is illustrated 600. A battery system index gauge can include one or more sensors, where the one or more sensors can include one or more of a voltage, current, impedance, temperature, leakage, or other sensor. The battery index gauge can include a display 610, where the display can render battery system index data. The rendering of the data can include an analog display (e.g., a meter), a digital display, a graph, and so on. The rendering of the data can include showing a value, a range of values, a percentage, a threshold, and the like. The rendering can include a system index qualification such as good, fair, poor, fail, replace, bypass, etc. The battery system index gauge can access a battery cell within a column of battery cells 620. The column of battery cells can be included within a battery system. Data can be collected by the battery system index gauge from a battery cell 622 using one or more probes, by accessing one or more sensors, etc. The accessing can be accomplished using wired or wireless techniques. In embodiments, the obtaining information on the battery cell is accomplished using near field communication.

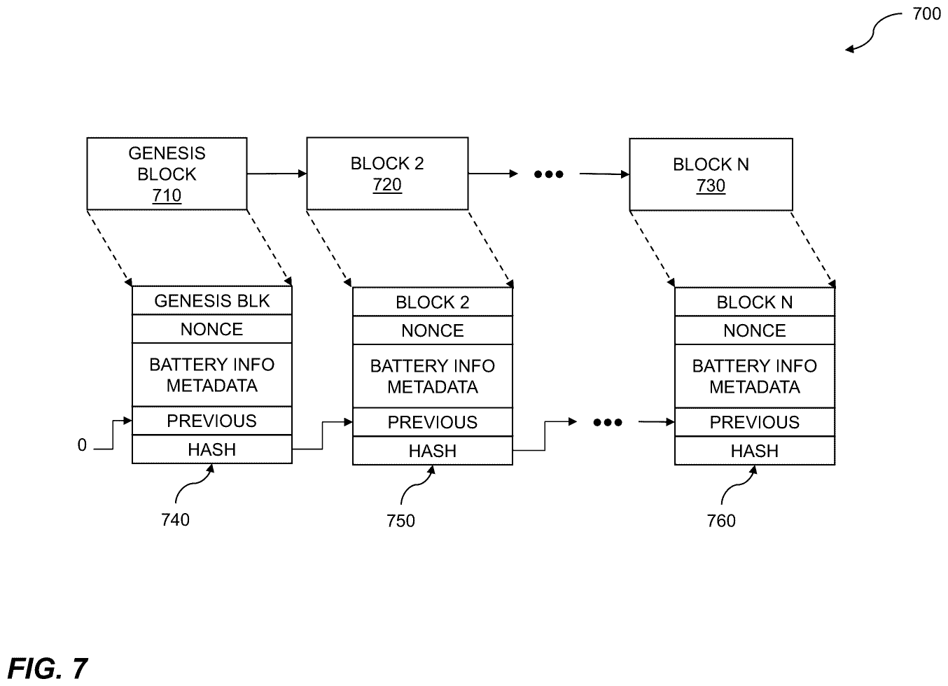

FIG. 7 shows a block diagram for a blockchain with battery information metadata. The blockchain can be based on an online digital ledger which can distributed across a plurality of servers. The blockchain can be used to track all transactions that are associated with an asset such as a dataset. The dataset can include metadata associated with battery information, where the battery information can be obtained from battery cells within a battery system. The blockchain with battery information metadata enables battery performance tracking across battery cells. A battery system comprising a plurality of battery cells is accessed, wherein the plurality of battery cells comprises a plurality of battery columns made up of battery cells arranged in series, wherein the plurality of battery columns is connected in parallel. Information on a battery cell within the plurality of battery cells is obtained, wherein the battery cell information is obtained using near field communication (NFC). The information on the battery cell is tracked by a column controller for a battery column from the plurality of battery columns, wherein the battery cell resides within the battery column. The information on the battery cell is stored for future reference. The information on the battery cell that was stored is analyzed. A capability metric is predicted for the battery cell based on the analyzing of the information on the battery cell.

An example blockchain with battery information metadata is shown 700. The example blockchain can be stored using one or more servers, where the servers can include cloud-based servers. The servers can include special-purpose servers such as blockchain servers. A blockchain can include a plurality of blocks, the number of which can increase as transactions associated with an asset such as a battery cell are executed. A transaction can include manufacturing a battery cell, deploying the battery cell, removing the battery cell from service, repurposing the battery cell, and so on. The blockchain is formed by starting with an initial block. The initial block can also be referred to as a genesis block 710. Each block within the blockchain can comprise multiple data sections. In embodiments, block 710 contains a nonce. The nonce can include a randomly generated, unique number. The nonce can be used for a variety of functions including cryptographic functions, authentication functions, and the like. Block 710 can further contain battery information metadata. The battery information metadata can include metadata about a battery cell. The metadata can include type of cell, date of manufacture, manufacturer, in-service date, usage history, removed-from-service date, second life redeployment date, battery state, etc. The block 710 can contain a value of a previous hash. In the edge case of block 710 being the genesis block, the value of the previous hash is set to a constant such as zero. The previous hash value associated with the genesis block can be set to a nonzero value. A hash value 740 can be computed for the genesis block.

Block 2 720 can represent the next block in the blockchain. Block 2 can be based on a structure that is similar to the genesis block 710. The hash 740 of block 710 can be used as the previous hash contents within block 2 720. When block 2 720 is created, a second hash value 750 can be computed and can be stored in the hash field 750 of block 2. New blocks can be added to the block chain as transactions such as changes in battery cell status are performed. The most recently created block, block N 730 can include the most recent battery information metadata. The previous hash field for block N 730 can use the hash field from block N−1 (not shown). A new hash value 760 can be computed for block N 730. As a new block is added to the blockchain, the hash value 760 can become the previous hash of the new block. In embodiments, the hash can be computed using an algorithm such as an MD5sum or another algorithm. Whenever battery information metadata is changed, such as changes associated with battery cell state, a new block can be added to the blockchain depicted in FIG. 7. While three blocks are shown in FIG. 7, in practice, many thousands of blocks can be included in the blockchain. A new block can be added each time metadata associated with battery information is changed, updated, added, and/or deleted.

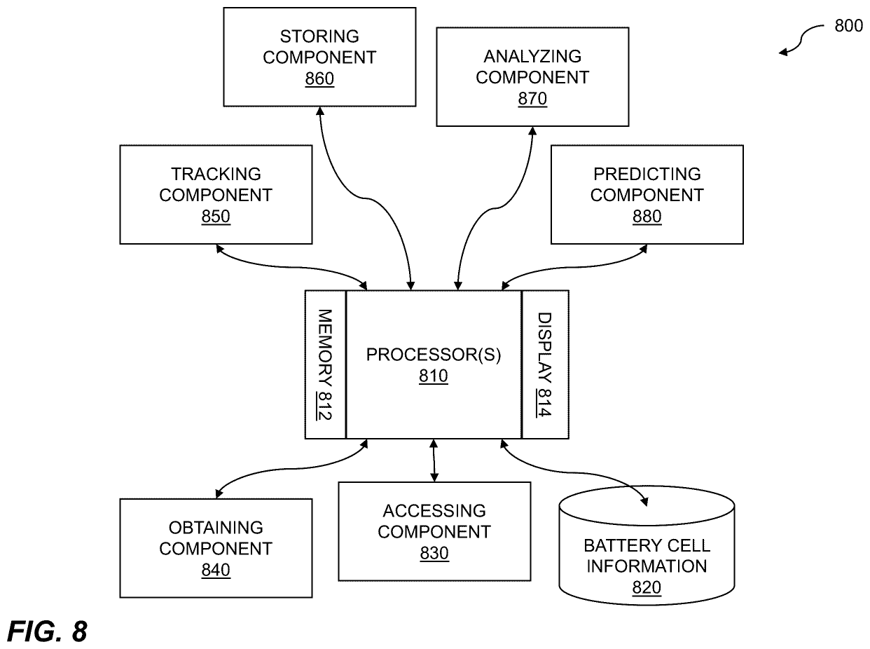

FIG. 8 is a system diagram for battery assessment. The battery assessment is enabled by battery performance tracking across battery cells. The system 800 can include one or more processors 810, which are attached to a memory 812 which stores instructions. The system 800 can further include a display 814 coupled to the one or more processors 810 for displaying data, intermediate steps, performance information, battery usability and capacity data, battery state, predicted capacity metric for a battery, remaining energy, and so on. In embodiments, one or more processors 810 are coupled to the memory 812, wherein the one or more processors, when executing the instructions which are stored, are configured to: access a battery system comprising a plurality of battery cells, wherein the plurality of battery cells comprises a plurality of battery columns made up of battery cells arranged in series, wherein the plurality of battery columns is connected in parallel; obtain information on a battery cell within the plurality of battery cells; track the information on the battery cell by a column controller for a battery column from the plurality of battery columns, wherein the battery cell resides within the battery column; store the information on the battery cell for future reference; analyze the information on the battery cell that was stored; and predict a capability metric for the battery cell based on analyzing of the information on the battery cell.

The system 800 can include battery cell information 820. The battery cell information 820 can include data associated with batteries that can form the battery system. The battery cell information can include physical parameters associated with the batteries, such as size, shape, weight, terminal configuration, battery chemical type, and so on. The system 800 can include an accessing component 830. The accessing component can access a battery system comprising a plurality of battery cells. The plurality of battery cells comprises a plurality of battery columns made up of battery cells arranged in series. The battery cells can be coupled to the battery column or decoupled from the battery columns. The decoupling can be accomplished by bypassing one or more battery cells. The plurality of battery columns is connected in parallel. In the battery system, the battery columns can include a quantity of battery cells arranged in series in order to attain a target voltage capability. The battery system can further include a quantity of battery columns arranged in parallel in order to attain a target current capability.

The system 800 can include an obtaining component 840. The obtaining component 840 can obtain information on a battery cell within the plurality of battery cells, wherein the battery cell information is obtained using near field communication (NFC). Embodiments include using built-in sensors coupled to the battery cell. Further battery cell information can be obtained using a barcode, a QR code, and so on. The battery cell information can be associated with various types of battery cells. The battery cells can include heterogeneous battery cells, homogeneous battery cells, etc. The battery cells can include cells based on a variety of rechargeable batteries such as sealed lead-acid (SLA), nickel-cadmium (NiCd), nickel-metal hydride (NiMH), lithium-ion (Li-ion), lithium-polymer (LiPo), lithium-iron-phosphate (LiFePO4), sodium-ion, lithium-metal, etc. The battery cell information can further include battery manufacturer, manufacture date, in-service date, removed from primary service date, charge/discharge count, and the like. The battery cell information can include a state of charge (SOC) for each battery cell, a state of health (SOH) for each battery cell, and so on. The battery cell information can include a source of energy that was used to charge the battery cell. In embodiments, the source of energy can include a green energy source. In embodiments, the battery cell information can further include a predicted capability metric for the battery cell (discussed below). The capability metric for the battery can be based on a state of charge for the battery cell, a state of health for the battery cell, an energy source used to charge the battery cell, etc. In embodiments, the information on the battery cell can include a number of charge cycles and a number of discharge cycles. A finite number of charge/discharge cycles can be associated with a rechargeable battery. The information on the battery can include location information associated with the battery system. Further information on the battery can include a state of charge (SOC) for each battery cell. The state of charge can be based on quality such as charged, useable, or needs recharging; a voltage; and so on. Other information on the battery cell can include a state of health (SOH) for each battery cell. The state of health of the battery can be based on battery cell storage capability, cell temperature, cell impedance, and the like.

The system 800 can include a tracking component 850. The tracking component 850 can track the information on the battery cell by a column controller for a battery column from the plurality of battery columns, wherein the battery cell resides within the battery column. The column controller can track abrupt changes in battery information such as a rapid increase in battery cell temperature, rapid decrease in battery cell internal impedance, etc. In embodiments, the column controller can include a cluster controller for a group of the plurality of battery cells. Abrupt changes can indicate a failing cell, a risk of cell combustion or explosion, and the like. In embodiments, the tracking the information can be accomplished for the battery cell over a life cycle for the battery cell. The tracking can include pattern analysis. In embodiments, the tracking can include usage pattern analysis and comparing against a warranty requirement. In a usage example, increased usage of a battery system can necessitate an increased number of charge/discharge cycles associated with the battery cells. Since the rechargeable battery cells are capable of handling a finite number of charge cycles, the lifespan of the battery system can be expected to decrease due to the higher number of charge/discharge cycles.

The system 800 can include a storing component 860. The storing component 860 can store the information on the battery cell for future reference. The storing of the information on the battery can be accomplished using local storage within a battery system, on-site storage in proximity to the battery system, remote storage, cloud-based storage, distributed storage, etc. In embodiments, the storing the information on the battery cell can be accomplished using blockchain technology. The system 800 can include an analyzing component 870. The analyzing component can monitor battery cell state of charge, cell health, temperature, internal impedance, etc. In embodiments, the analyzing the information can include recording regulatory information. The regulatory information can include battery system safety compliance, net metering, adherence to use of green energy sources, and the like. In embodiments, the analyzing the information can include evaluating performance against sustainability goals. The analysis can be associated with a service level agreement for providing power from the battery system. In embodiments, the analyzing can include evaluating abnormal data that impacts a service level agreement (SLA). A service level agreement describes voltage and current level parameters; reliability and availability requirements, etc. Abnormal data associated with battery cells can indicate battery cell diminished capability, failure, and so on, requiring battery system reconfiguration, battery cell, column, or system replacement, and the like.

The system 800 can include a predicting component 880. The predicting component 880 can predict a capability metric for the battery cell based on the analyzing of the information on the battery cell. The capability metric can be used to match a battery cell to a battery column, a battery column to a battery system, and so on. The capability metric can be used to match a battery system to a power requirement specification. The capability metric can further be used to gauge effectiveness of green energy source usage. Further embodiments include aggregating the capability metric for the battery cell with capability metrics from other cells from the plurality of cells, wherein the other cells reside within a same column as the battery cell for which the capability metric was predicted, to produce a column capability metric. The aggregating capability metric for battery cells can enable improved performance, higher storage capability, lower leakage, etc., associated with the battery column. Further embodiments include aggregating the column capability metric with capability metrics from other battery columns to produce a battery system capability metric. The aggregating column capability metrics can be used to improve battery system performance, reliability, etc. In embodiments, the capability metric can include voltage, power, energy, or number of cycles. The capability metric of a battery system can be used for a variety of energy purposes. Embodiments further include performing energy trading based on the capability metric for the battery cell. Energy provided by energy sources such as green energy sources can be used to charge the battery system. Further, the battery system can be charged while energy prices are comparatively low. Further embodiments include providing power from the battery system to a power grid based on the capability metric. Providing power to a power grid can provide power during peak power demand events. The providing power can be provided on a net-metering basis.

The system 800 can include a computer program product embodied in a non-transitory computer readable medium for battery assessment, the computer program product comprising code which causes one or more processors to perform operations of: accessing a battery system comprising a plurality of battery cells, wherein the plurality of battery cells comprises a plurality of battery columns made up of battery cells arranged in series, wherein the plurality of battery columns is connected in parallel; obtaining information on a battery cell within the plurality of battery cells; tracking the information on the battery cell by a column controller for a battery column from the plurality of battery columns, wherein the battery cell resides within the battery column; storing the information on the battery cell for future reference; analyzing the information on the battery cell that was stored; and predicting a capability metric for the battery cell based on the analyzing of the information on the battery cell.

Each of the above methods may be executed on one or more processors on one or more computer systems. Embodiments may include various forms of distributed computing, client/server computing, and cloud-based computing. Further, it will be understood that the depicted steps or boxes contained in this disclosure's flow charts are solely illustrative and explanatory. The steps may be modified, omitted, repeated, or re-ordered without departing from the scope of this disclosure. Further, each step may contain one or more sub-steps. While the foregoing drawings and description set forth functional aspects of the disclosed systems, no particular implementation or arrangement of software and/or hardware should be inferred from these descriptions unless explicitly stated or otherwise clear from the context. All such arrangements of software and/or hardware are intended to fall within the scope of this disclosure.

The block diagrams and flowchart illustrations depict methods, apparatus, systems, and computer program products. The elements and combinations of elements in the block diagrams and flow diagrams, show functions, steps, or groups of steps of the methods, apparatus, systems, computer program products and/or computer-implemented methods. Any and all such functions—generally referred to herein as a “circuit”, “module”, or “system”— may be implemented by computer program instructions, by special-purpose hardware-based computer systems, by combinations of special purpose hardware and computer instructions, by combinations of general-purpose hardware and computer instructions, and so on.

A programmable apparatus which executes any of the above-mentioned computer program products or computer-implemented methods may include one or more microprocessors, microcontrollers, embedded microcontrollers, programmable digital signal processors, programmable devices, programmable gate arrays, programmable array logic, memory devices, application specific integrated circuits, or the like. Each may be suitably employed or configured to process computer program instructions, execute computer logic, store computer data, and so on.

It will be understood that a computer may include a computer program product from a computer-readable storage medium and that this medium may be internal or external, removable and replaceable, or fixed. In addition, a computer may include a Basic Input/Output System (BIOS), firmware, an operating system, a database, or the like that may include, interface with, or support the software and hardware described herein.

Embodiments of the present invention are limited to neither conventional computer applications nor the programmable apparatus that run them. To illustrate: the embodiments of the presently claimed invention could include an optical computer, quantum computer, analog computer, or the like. A computer program may be loaded onto a computer to produce a particular machine that may perform any and all of the depicted functions. This particular machine provides a means for carrying out any and all of the depicted functions.

Any combination of one or more computer readable media may be utilized including but not limited to: a non-transitory computer readable medium for storage; an electronic, magnetic, optical, electromagnetic, infrared, or semiconductor computer readable storage medium or any suitable combination of the foregoing; a portable computer diskette; a hard disk; a random access memory (RAM); a read-only memory (ROM); an erasable programmable read-only memory (EPROM, Flash, MRAM, FeRAM, or phase change memory); an optical fiber; a portable compact disc; an optical storage device; a magnetic storage device; or any suitable combination of the foregoing. In the context of this document, a computer readable storage medium may be any tangible medium that can contain or store a program for use by or in connection with an instruction execution system, apparatus, or device.

It will be appreciated that computer program instructions may include computer executable code. A variety of languages for expressing computer program instructions may include without limitation C, C++, Java, JavaScript™, ActionScript™, assembly language, Lisp, Perl, Tcl, Python, Ruby, hardware description languages, database programming languages, functional programming languages, imperative programming languages, and so on. In embodiments, computer program instructions may be stored, compiled, or interpreted to run on a computer, a programmable data processing apparatus, a heterogeneous combination of processors or processor architectures, and so on. Without limitation, embodiments of the present invention may take the form of web-based computer software, which includes client/server software, software-as-a-service, peer-to-peer software, or the like.

In embodiments, a computer may enable execution of computer program instructions including multiple programs or threads. The multiple programs or threads may be processed approximately simultaneously to enhance utilization of the processor and to facilitate substantially simultaneous functions. By way of implementation, any and all methods, program codes, program instructions, and the like described herein may be implemented in one or more threads which may in turn spawn other threads, which may themselves have priorities associated with them. In some embodiments, a computer may process these threads based on priority or other order.

Unless explicitly stated or otherwise clear from the context, the verbs “execute” and “process” may be used interchangeably to indicate execute, process, interpret, compile, assemble, link, load, or a combination of the foregoing. Therefore, embodiments that execute or process computer program instructions, computer-executable code, or the like may act upon the instructions or code in any and all of the ways described. Further, the method steps shown are intended to include any suitable method of causing one or more parties or entities to perform the steps. The parties performing a step, or portion of a step, need not be located within a particular geographic location or country boundary. For instance, if an entity located within the United States causes a method step, or portion thereof, to be performed outside of the United States, then the method is considered to be performed in the United States by virtue of the causal entity.

While the invention has been disclosed in connection with preferred embodiments shown and described in detail, various modifications and improvements thereon will become apparent to those skilled in the art. Accordingly, the foregoing examples should not limit the spirit and scope of the present invention; rather it should be understood in the broadest sense allowable by law.

What is claimed is:

1. A processor-implemented method for battery assessment comprising:
accessing a battery system comprising a plurality of battery cells, wherein the plurality of battery cells comprises a plurality of battery columns made up of battery cells arranged in series, wherein the plurality of battery columns is connected in parallel;
obtaining information on a battery cell within the plurality of battery cells;
tracking the information on the battery cell by a column controller for a battery column from the plurality of battery columns, wherein the battery cell resides within the battery column;
storing the information on the battery cell for future reference;
analyzing the information on the battery cell that was stored; and
predicting a capability metric for the battery cell based on the analyzing of the information on the battery cell.

2. The method of claim 1 wherein the battery cell information is obtained using near field communication (NFC).

3. The method of claim 1 wherein the information on the battery cell includes a number of charge cycles and a number of discharge cycles.

4. The method of claim 1 wherein the information on the battery cell includes a source of energy that was used to charge the battery cell.

5. The method of claim 4 wherein the source of energy includes a renewable energy source.

6. The method of claim 5 wherein a quantification number is calculated for an amount of carbon saved based on the renewable energy source.

7. The method of claim 1 wherein the information is obtained using built-in sensors coupled to the battery cell.

8. The method of claim 1 further comprising using location-based technology to track a location for the battery system.

9. The method of claim 1 wherein the analyzing the information includes recording regulatory information.

10. The method of claim 1 wherein the analyzing the information includes evaluating performance against sustainability goals.

11. The method of claim 1 wherein the tracking the information is accomplished for the battery cell over a life cycle for the battery cell.

12. The method of claim 1 wherein the column controller includes a cluster controller for a group of the plurality of battery cells.

13. The method of claim 1 further comprising aggregating the capability metric for the battery cell with capability metrics from other battery cells from the plurality of cells, wherein the other cells reside within a same column as the battery cell for which the capability metric was predicted, to produce a column capability metric.

14. The method of claim 13 further comprising aggregating the column capability metric with capability metrics from other battery columns to produce a battery system capability metric.

15. The method of claim 1 further comprising profiling the battery cell in comparison to other battery cells within the plurality of battery cells to produce a battery cell profile.

16. The method of claim 15 further comprising swapping out the battery cell based on the battery cell profile.

17. The method of claim 1 wherein the tracking the information on the battery cell is performed over time to determine a change in performance of the battery cell.

18. The method of claim 1 further comprising obtaining information on a second battery cell within a same battery column as the battery cell, tracking the information on the second battery cell, and predicting a capability metric for the second battery cell.

19. The method of claim 18 further comprising bypassing the battery cell and enabling the second battery cell, using software-controlled switches, based on the capability metric for the battery cell and the capability metric for the second battery cell.

20. The method of claim 1 further comprising managing user contracts for the battery system based on the information for the battery cell that was tracked.

21. The method of claim 20 wherein the managing includes comparing a contracted amount versus an available amount based on the capability metric.

22. The method of claim 20 wherein the tracking includes usage pattern analysis and comparing against a warranty requirement.

23. The method of claim 20 wherein the analyzing includes evaluating abnormal data that impacts a service level agreement (SLA).

24. The method of claim 1 further comprising performing energy trading based on the capability metric for the battery cell.

25. The method of claim 1 further comprising providing power from the battery system to a power grid based on the capability metric.

26. A computer program product embodied in a non-transitory computer readable medium for battery assessment, the computer program product comprising code which causes one or more processors to perform operations of:
accessing a battery system comprising a plurality of battery cells, wherein the plurality of battery cells comprises a plurality of battery columns made up of battery cells arranged in series, wherein the plurality of battery columns is connected in parallel;
obtaining information on a battery cell within the plurality of battery cells;
tracking the information on the battery cell by a column controller for a battery column from the plurality of battery columns, wherein the battery cell resides within the battery column;
storing the information on the battery cell for future reference;
analyzing the information on the battery cell that was stored; and
predicting a capability metric for the battery cell based on the analyzing of the information on the battery cell.

27. A computer system for task processing comprising:
a memory which stores instructions;
one or more processors coupled to the memory, wherein the one or more processors, when executing the instructions which are stored, are configured to:
access a battery system comprising a plurality of battery cells, wherein the plurality of battery cells comprises a plurality of battery columns made up of battery cells arranged in series, wherein the plurality of battery columns is connected in parallel;
obtain information on a battery cell within the plurality of battery cells;
track the information on the battery cell by a column controller for a battery column from the plurality of battery columns, wherein the battery cell resides within the battery column;
store the information on the battery cell for future reference;
analyze the information on the battery cell that was stored; and
predict a capability metric for the battery cell based on analyzing of the information on the battery cell.
